(19) United States
(12) Patent Application Publication
(10) Pub. No.: US 2013/0133444 A1
(43) Pub. Date: May 30, 2013

(54) HEAD ELEMENT INSPECTION APPARATUS

(71) Applicant: Hitachi High-Technologies Corporation, Tokyo (JP)

(72) Inventors: Yoshinori KITANO, Kamisato-machi (JP); Teruaki TOKUTOMI, Kamisato-machi (JP); Akira TOBITA, Kamisato-machi (JP)

(73) Assignee: HITACHI HIGH-TECHNOLOGIES CORPORATION, Tokyo (JP)

(21) Appl. No.: 13/687,217

(22) Filed: Nov. 28, 2012

(30) Foreign Application Priority Data
Nov. 29, 2011 (JP) 2011-260439

(51) Int. Cl. G01R 33/12

(52) U.S. Cl. CPC G01R 33/1207
USPC 73/864.91

(57) ABSTRACT

There is provided a head element inspection apparatus that can adjust the position of a cantilever for a short time without using any adjusting jig in the case of replacing a cantilever. A head element inspection apparatus includes a cantilever holder that holds a cantilever, a holder base on which the cantilever holder is mounted, a Z-direction drive shaft that drives the holder base in the Z-direction, and a workpiece table that holds a head element and drives the head element in X- and Y-directions. The cantilever holder and the holder base include adjusting mechanisms (an adjusting screw and an off-center pin) that adjust the position of the cantilever in the X-direction and the Y-direction.

### CLAIM OF PRIORITY

The present application claims priority from Japanese Patent application serial No. JP2011-260439, filed on Nov. 29, 2011, the content of which is hereby incorporated by reference into this application.

### BACKGROUND OF THE INVENTION

(1) Field of the Invention

The present invention relates to a head element inspection apparatus that inspects the effective magnetic track width or the like of a head element.

(2) Description of the Related Art

In order to measure the shape of a magnetic field generated from a thin film magnetic head and inspect the effective magnetic track width or the like, a head element inspection apparatus such as a magnetic force microscope (MFM) of high resolution at atomic size level is used. The magnetic force microscope includes a cantilever that detects a magnetic field, in which the cantilever is scanned and moved over a head element for measuring the shape of a magnetic field. In starting inspection in the head element inspection apparatus, it is necessary to position the cantilever at a reference position.

For a technique related to the positioning of the cantilever, Japanese Patent Application Laid-Open Publication No. 2004-20534 describes a configuration for the purpose of more simply performing the positioning work of a cantilever for a shorter time, in which an adjusting jig is used to move a holder slider holding the cantilever at a reference position with respect to a holder base and a lever holder (the holder base and the holder slider) is mounted on the lever holder holding unit of a scanning probe microscope.

### SUMMARY OF THE INVENTION

In the conventional technique described in Japanese Patent Application Laid-Open Publication No. 2004-20534, in the case of replacing a cantilever, the adjusting jig is used to position the cantilever at the reference position, the cantilever is held on the cantilever holder (the lever holder), and the cantilever holder is mounted on the inspection apparatus. However, this method needs to separately prepare the adjusting jig and to provide an adjusting work space. In the case of using a plurality of jigs, it is necessary to adjust gaps between the jigs so as not to vary positions adjusted using the jigs. Moreover, it is likely that a position shift occurs in mounting the cantilever holder, on which the cantilever is positioned, on the inspection apparatus. In the case where a position shift occurs, it is necessary to again adjust positions, causing an increase in adjusting time.

It is an object of the present invention to provide a head element inspection apparatus that can adjust the position of a cantilever for a short time without using any adjusting jig in the case of replacing a cantilever.

According to the present invention, there is provided a head element inspection apparatus that inspects a characteristic of a head element using a cantilever. The head element inspection apparatus includes: a cantilever holder configured to hold the cantilever; a holder base on which the cantilever holder is mounted; a Z-direction drive shaft configured to drive the holder base in a Z-direction; and a workpiece table configured to hold the head element and drive the head element in X- and Y-directions. The cantilever holder and the holder base include adjusting mechanisms configured to adjust a position of the cantilever in the X-direction and in the Y-direction.

According to the present invention, the position is adjusted after mounting the cantilever on the head element inspection apparatus, so that the adjusting jig and the adjusting work space are eliminated. Moreover, positioning is completed by adjustment for one time regardless of mounting error or individual differences between components, so that replacement time for cantilevers can be shortened greatly.

### BRIEF DESCRIPTION OF THE DRAWINGS

The present invention will become fully understood from the detailed description given hereinafter and the accompanying drawings, wherein:

FIG. 1 is a diagram of the appearance of an embodiment of a head inspection system;

FIG. 2 is a diagram of the configuration of a mechanism unit of a head element inspection apparatus;

FIGS. 3A and 3B are detailed diagrams of a holder base unit;

FIGS. 4A, 4B, and 4C are detailed diagrams of a cantilever holder;

FIGS. 5A and 5B are enlarged diagrams of a method for holding a cantilever;

FIG. 6 is an enlarged diagram of a method for mounting the cantilever holder; and

FIG. 7 is a diagram of a method for adjusting the position of the cantilever 5 using a monitor.

### DETAILED DESCRIPTION OF THE EMBODIMENT

In the following, an embodiment of the present invention will be described with reference to the drawings.

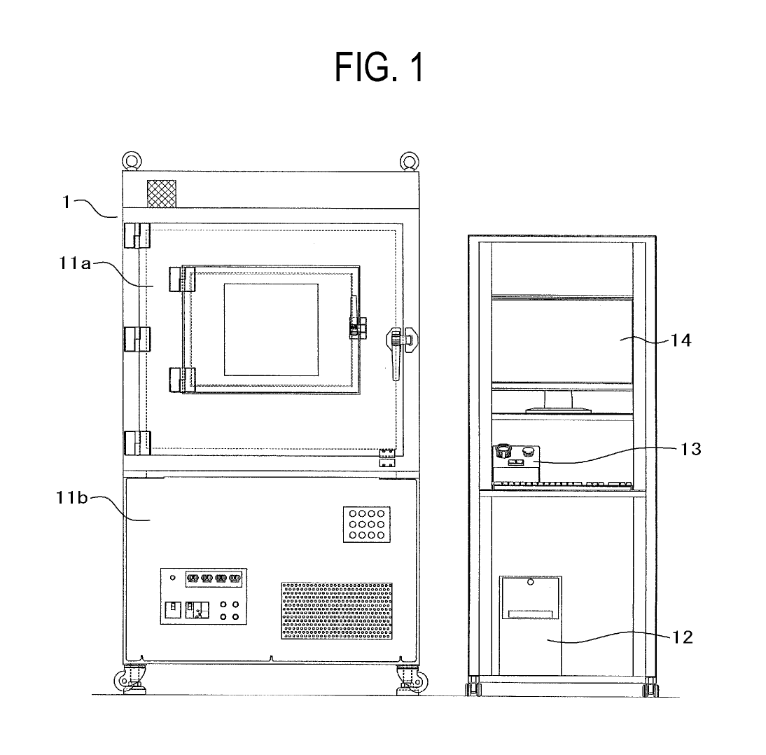

FIG. 1 is a diagram of the appearance of an embodiment of a head inspection system including a head element inspection apparatus. In the head element inspection apparatus, the shape of a magnetic field generated from a recording head element is measured using a magnetic force microscope (MFM), and the effective magnetic track width is inspected in a nondestructive manner; the recording head element is included in a row-bar thin film magnetic head cut out of a wafer in the manufacture process steps of a thin film magnetic head. In this inspection, a record signal (an excitation signal) is inputted from the bonding pads of the head elements, a cantilever (a magnetic probe) is scanned and moved at a location corresponding to the floating height of the magnetic head, and the shape of a magnetic field generated from the head element is measured.

The configuration of a head element inspection apparatus 1 includes a frame A (11a) in which a mechanism unit 2 of a magnetic force microscope is accommodated, a driver for a mechanism unit 2, a control board that controls measurement and inspection, and a frame B (11b) in which a power supply or the like necessary for the components is accommodated. The head element inspection apparatus 1 further includes a control PC 12 that controls and operates the head element inspection apparatus 1, an apparatus power supply manipulating unit 13, and a monitor 14 that displays measured results.

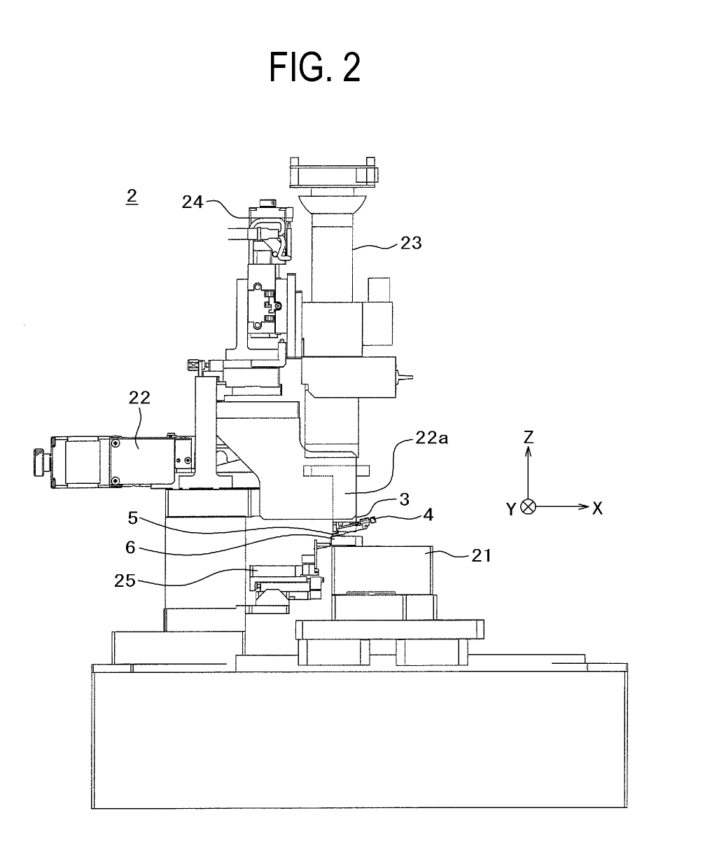

FIG. 2 is a diagram of the configuration of the mechanism unit 2 of the head element inspection apparatus 1. In the following, the X-, Y-, and Z-axis directions of the apparatus are defined as illustrated for description.

A workpiece table 21 includes a two-axial drive shaft (a coarse adjustment shaft) that chucks and holds a workpiece (a row-bar thin film magnetic head) 6 and drives the workpiece 6 in the X- and Y-directions and a piezo element that finely drives the workpiece 6. A cantilever Z-direction drive shaft (the coarse adjustment shaft) 22 drives the cantilever 5 in the Z-direction, moves the cantilever 5 to a predetermined height from the workpiece 6 (a location corresponding to the floating height of the magnetic head), and moves the cantilever 5 at a retract position when inspection is not performed. A holder base unit 3 is provided at a tip end portion 22a of the cantilever Z-direction drive shaft 22, and the cantilever 5 is mounted on the holder base unit 3 through a cantilever holder 4, described later. Moreover, the piezo element that finely moves the cantilever 5 in the Z-direction is mounted on the tip end portion 22a for minimizing a weight driven by the piezo element.

A camera 23 takes the surface shape of the workpiece 6, and displays the surface on the monitor 14. The taken image is used for the position alignment of the workpiece 6, and used for position adjustment when replacing the cantilever 5. A camera Z-direction drive shaft 24 adjusts the focus of the camera 23. A power feed unit 25 receives a record signal (an excitation signal) from the bonding pad of the workpiece 6.

An operator sets a case in which a plurality of workpieces 6 are accommodated at a predetermined position on the head element inspection apparatus 1. When the control PC 12 is operated, a transfer robot, not shown, takes workpieces 6 one by one out of the case, carries the workpieces 6 to the workpiece table 21, and returns the workpieces 6 that inspection and measurement are finished to the case.

In the following, mounting mechanisms around the cantilever 5 will be described in detail.

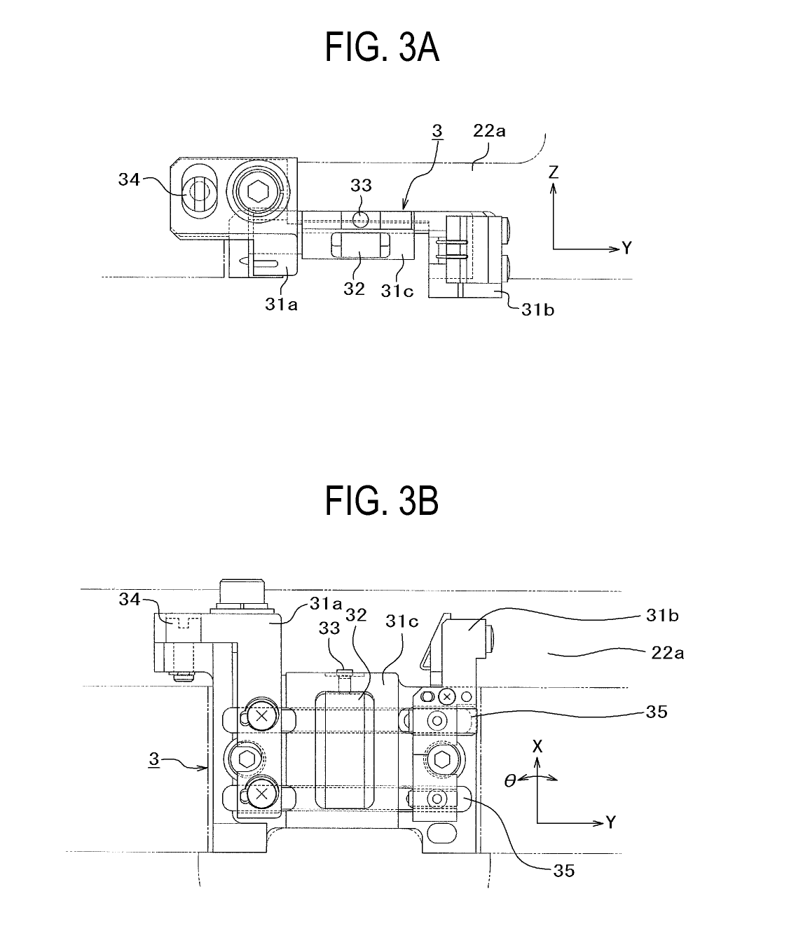

FIGS. 3A and 3B are detailed diagrams of the holder base unit 3. FIG. 3A is a diagram that the holder base unit 3 is seen from the X-direction, and FIG. 3B is a diagram that the holder base unit 3 is seen from the Z-direction. The holder base unit 3 is disposed on the lower side of the tip end portion 22a of the cantilever Z-direction drive shaft 22 (in the Z-direction), and is a component on which the cantilever holder 4 is mounted. It is noted that the cantilever holder 4 is omitted in FIGS. 3A and 3B.

The holder base unit 3 has an integrated structure in which a holder base (a reference) 31a, a holder base (a retainer) 31b, and a holder base (a bottom face) 31c are joined to each other, and the holder base unit 3 includes a recessed portion. The cantilever holder 4 is inserted into this recessed portion, and the holder base (the bottom face) 31c includes a chuck magnet 32 that chucks and holds the cantilever holder 4. It is noted that the contacting surface of the holder base (the bottom face) 31c to contact with the cantilever holder 4 is not in parallel with the X-Y plane, and tilted at a predetermined angle in the Z-direction. This is because the cantilever holder 4 (the cantilever 5) is mounted as tilted at a predetermined angle.

A reference pin 33 mounted on the holder base (the bottom face) 31c provides a reference position in the X-direction when holding the cantilever holder 4. A plunger 35 mounted on the holder base (the retainer) 31b presses the cantilever holder 4 to the holder base (the reference) 31a for positioning the cantilever holder 4 in a O-direction. A spring material such as a plate spring may be used for the plunger 35. An off-center pin 34 mounted on the holder base (the reference) 31a has an off-center structure, in which the off-center pin 34 is rotated to move the holder bases 31a, 31b, and 31c joined to each other in the Y-direction for positioning the cantilever holder 4 in the Y-direction.

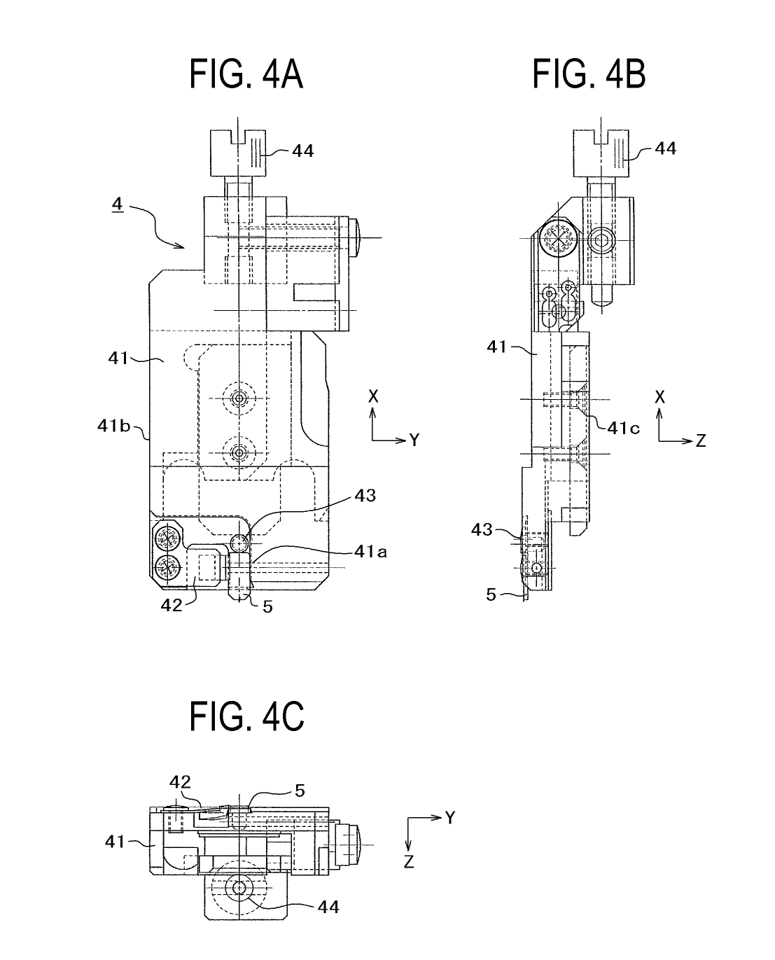

FIGS. 4A, 4B, and 4C are detailed diagrams of the cantilever holder 4.

FIG. 4A is a diagram that the cantilever holder 4 is seen from the Z-direction, FIG. 4B is a diagram that the cantilever holder 4 is seen from the Y-direction, and FIG. 4C is a diagram that the cantilever holder 4 is seen from the X-direction.

The cantilever holder 4 holds the cantilever 5 on a holder positioning portion 41a of a holder main body 41. In order to highly accurately hold the cantilever 5, the cantilever holder 4 includes a retainer spring 42 that retains the cantilever 5 in the Z-direction, a reference pin 43 that positions the cantilever in the X-direction when mounting the cantilever 5, and an adjusting screw 44 that adjusts the position in the X-direction after mounting the cantilever 5 on the holder base unit 3. A holder reference surface 41b and a holder contacting surface 41c of the holder main body 41 are mounted on the holder base (the reference) 31a of the holder base unit 3 and the holder base (the bottom face) 31c, respectively.

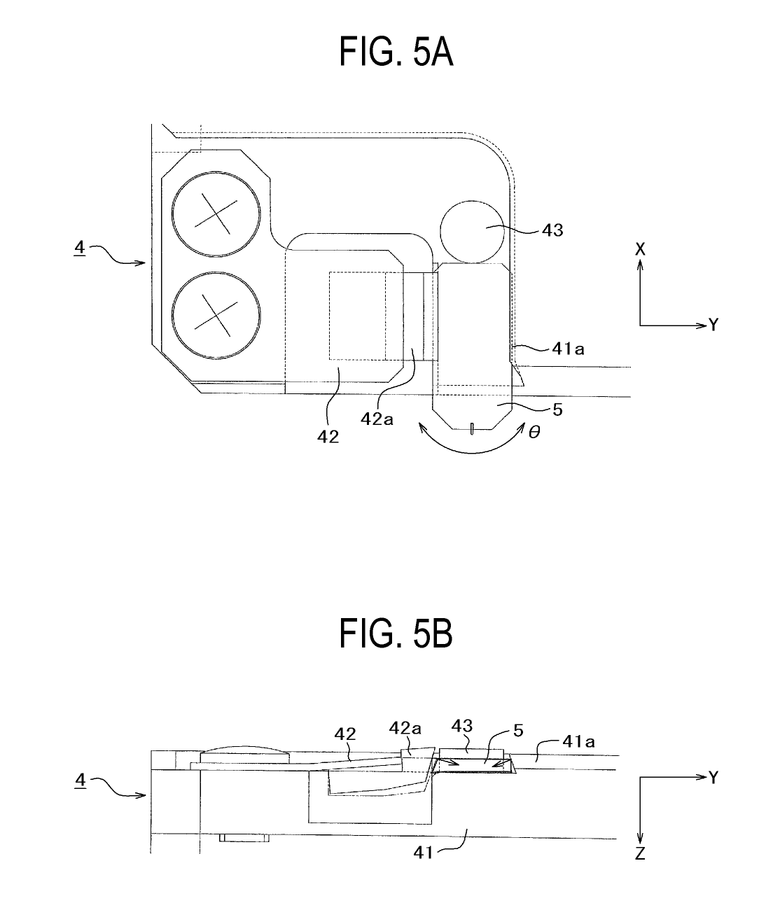

FIGS. 5A and 5B are enlarged diagrams of a method for holding the cantilever 5. FIG. 5A is a diagram that the cantilever holder 4 and the cantilever 5 are seen from the Z-direction, and FIG. 5B is a diagram that the cantilever holder 4 and the cantilever 5 are seen from the X-direction.

The cantilever 5 is held as sandwiched between the holder positioning portion 41a and the retainer spring 42 of the cantilever holder 4. When holding the cantilever 5, the holder positioning portion 41a and a tip end portion 42a of the retainer spring 42 with which the cantilever 5 contacts are in a tapered shape. The tip end portion 42a retains the cantilever 5, so that the cantilever 5 is prevented from floating up and the cantilever 5 is pressed in the direction of the holder positioning portion 41a. On the other hand, the holder positioning portion 41a positions the retained cantilever 5 in the O-direction, and also prevents the cantilever 5 from floating up because of the tapered shape. Thus, the cantilever 5 is held on the cantilever holder 4 in the state in which the cantilever 5 is positioned in the O-direction.

Moreover, the cantilever 5 is positioned in the X-direction by pressing the cantilever 5 to the reference pin 43 until the cantilever 5 contacts with the reference pin 43.

The contacting portions with the cantilever 5 are thus formed in the tapered shape, so that the same effect can be exerted without adjusting positions or replacing components even though the thickness of the cantilever 5 to be replaced is varied more or less because of individual differences between the cantilevers 5.

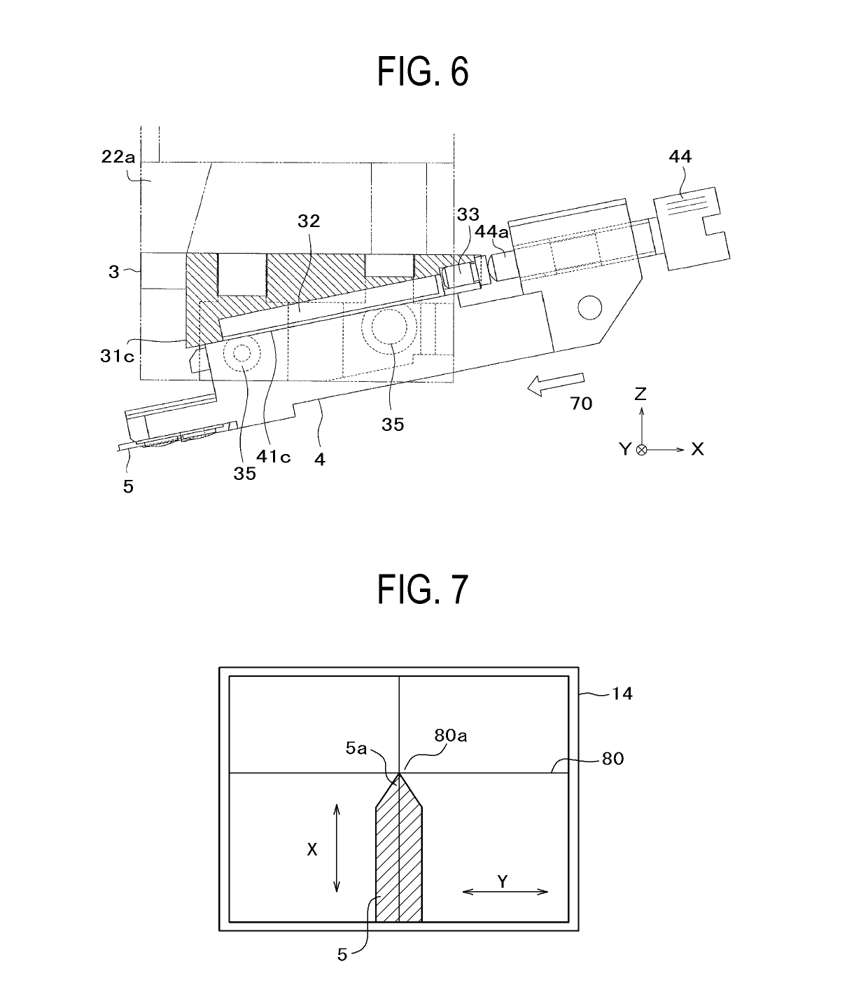

FIG. 6 is an enlarged diagram of a method for mounting the cantilever holder 4, which is seen from the Y-direction. The cantilever holder 4 holding the cantilever 5 is inserted into the direction of an arrow 70 along the holder base 31c while attracting the holder contacting surface 41c to the chuck magnet 32 of the holder base unit 3. The cantilever holder 4 after inserted is held by the attracting force of the chuck magnet 32 and the pressing force of the plunger 35. In the insertion, since the cantilever holder 4 is pressed against the holder base (the reference) 31a by the plunger 35 illustrated in FIG. 3B, the cantilever holder 4 is positioned in the O-direction. Moreover, tip end 44a of the adjusting screw 44 is inserted until the tip end 44a contacts with the reference pin 33 of the holder base unit 3 when inserting the cantilever holder 4, so that the cantilever holder 4 is positioned also in the X-direction.

Subsequently, after mounting the cantilever holder 4 on the holder base unit 3, the cantilever 5 is taken by the camera 23, and the X- and Y-positions of the cantilever 5 are adjusted using the image on the monitor 14.

FIG. 7 is a diagram of a method for adjusting the position of the cantilever 5 using the monitor 14. A cross marker 80 to be a reference for positioning is displayed beforehand on a monitor screen, and the image of the cantilever 5 taken by the camera 23 is displayed. The cantilever 5 is then adjusted while observing the screen in such a way that a tip end 5a of the cantilever 5 comes to an intersection position 80a of the marker 80.

In adjusting, the off-center pin 34 of the holder base unit 3 is rotated to move the cantilever 5 in the Y-direction. Moreover, the adjusting screw 44 of the cantilever holder 4 is rotated to move the cantilever 5 in the X-direction. Therefore, a position shift caused by individual differences between the cantilevers 5 or caused by mounting error due to replacement can be corrected. It is noted that the marker 80 may be a mark other than the cross mark, and the positioning portion for the cantilever 5 may be a portion other than the tip end.

According to the embodiment, the adjusting mechanisms (the off-center pin 34 and the adjusting screw 44) are provided on the holder base unit 3 and the cantilever holder 4 of the head element inspection apparatus 1, so that it is possible that the cantilever 5 to be replaced is coarsely positioned and mounted and then the position of the cantilever 5 is finally adjusted using the adjusting mechanisms. As a result, it is unnecessary to adjust the cantilever at the reference position before mounting the cantilever on the head element inspection apparatus as in the conventional method, and the adjusting jig and the adjusting work space for use in adjustment are eliminated. Both of the adjusting mechanisms additionally provided in the embodiment are in simple structures, which do not upsize the head element inspection apparatus 1.

Moreover, in the conventional method, even though the adjusting jig is used to adjust the position of the cantilever, a position shift sometimes occurs in mounting the cantilever on the inspection apparatus, causing a necessity of readjustment. However, according to the embodiment, readjustment does not occur. Namely, positioning is completed by only a single adjustment with no influence of mounting error or individual differences between components, so that it is possible to greatly shorten adjusting time.

In the foregoing embodiment, the inspection of the effective track width of the magnetic head using the magnetic force microscope (MFM) is taken as an example of the function of the head element inspection apparatus. However, the present invention is not limited to this example. The present invention can be similarly applied to a scanning probe microscope (SPM) that measures the characteristics of a head element using a cantilever at atomic size level such as a scanning tunneling microscope (STM) and an atomic force microscope (AFM).

What is claimed is:

1. A head element inspection apparatus that inspects a characteristic of a head element using a cantilever, the head element inspection apparatus comprising:
a cantilever holder configured to hold the cantilever;
a holder base on which the cantilever holder is mounted;
a Z-direction drive shaft configured to drive the holder base in a Z-direction; and
a workpiece table configured to hold the head element and drive the head element in X- and Y-directions,
wherein the cantilever holder and the holder base include adjusting mechanisms configured to adjust a position of the cantilever in the X-direction and in the Y-direction.

2. The head element inspection apparatus according to claim 1, wherein:
as the adjusting mechanisms for the cantilever,
the cantilever holder includes an adjusting screw configured to move the cantilever holder in the X-direction with respect to the holder base; and
the holder base includes an off-center pin configured to move the cantilever holder in the Y-direction with respect to the holder base.

3. The head element inspection apparatus according to claim 1, wherein:
the cantilever holder holds the cantilever at a reference position using a reference pin and a retainer spring; and
the holder base mounts the cantilever holder at the reference position using a chuck magnet and a plunger.

4. The head element inspection apparatus according to claim 2, wherein:
the cantilever holder holds the cantilever at a reference position using a reference pin and a retainer spring; and
the holder base mounts the cantilever holder at the reference position using a chuck magnet and a plunger.
